(19) United States
(12) Patent Application Publication
(10) Pub. No.: US 2025/0354265 A1
(43) Pub. Date: Nov. 20, 2025

(54) SUBSTRATE PROCESSING APPARATUS AND SUBSTRATE PROCESSING METHOD

(71) Applicant: Tokyo Electron Limited, Tokyo (JP)

(72) Inventors: Junnosuke TAGUCHI, Iwate (JP); Takuya OIKAWA, Iwate (JP); Yasushi TAKEUCHI, Iwate (JP)

(21) Appl. No.: 19/185,795

(22) Filed: Apr. 22, 2025

(30) Foreign Application Priority Data
May 20, 2024 (JP) 2024-082035

(51) Int. Cl. C23C 16/458; C23C 16/455; C23C 16/52; H01L 21/687

(52) U.S. Cl. CPC C23C 16/4584; C23C 16/45544; C23C 16/52; H01L 21/68764

(57) ABSTRACT

A substrate processing apparatus includes a processing container, a rotary table rotatably provided inside the processing container, a mounting table for mounting a substrate thereon, the mounting table being configured to be integrally rotatable with the rotary table and to be rotatable relative to the rotary table at a position away from a rotation center of the rotary table, and a controller configured to control rotation of the rotary table and rotation of the mounting table. The controller controls rotation of the rotary table and rotation of the mounting table in such a manner that an axial-rotation centrifugal force generated by rotation of the mounting table is larger than a revolution centrifugal force generated by rotation of the rotary table.

### CROSS-REFERENCE TO RELATED APPLICATIONS

Priority is claimed to Japanese Patent Application No. 2024-082035, filed May 20, 2024, the entire content of which is incorporated herein by reference.

### BACKGROUND

### 1. Technical Field

The present disclosure relates to a substrate processing apparatus and a substrate processing method.

### 2. Description of Related Art

Japanese Unexamined Patent Application Publication No. 2021-111758 (hereinafter “Patent Document 1”) discloses a substrate processing apparatus including a processing container (vacuum container) and a rotary table rotatably (revolvingly) provided in the processing container. The substrate processing apparatus includes a plurality of mounting tables for mounting a substrate thereon at positions spaced apart from a rotation center of the rotary table, in the circumferential direction. Each of the mounting tables is configured to be rotatable integrally with the rotary table and rotatable (axially rotatable) relative to the rotary table.

Each substrate mounted on each mounting table of the substrate processing apparatus is moved within each mounting table upon receipt of a centrifugal force caused by rotation of the rotary table. In particular, in the substrate processing apparatus, the chance of a substrate moving increases as the position of the substrate in the mounting table is changed by rotation of the mounting table. Particles are easily generated by the movement of a substrate.

### SUMMARY

According to an aspect of the present disclosure, a substrate processing apparatus includes a processing container, a rotary table rotatably provided inside the processing container, a mounting table for mounting a substrate thereon, the mounting table being configured to be integrally rotatable with the rotary table and to be rotatable relative to the rotary table at a position away from a rotation center of the rotary table, and a controller configured to control rotation of the rotary table and rotation of the mounting table. The controller controls rotation of the rotary table and rotation of the mounting table in such a manner that an axial-rotation centrifugal force generated by rotation of the mounting table is larger than a revolution centrifugal force generated by rotation of the rotary table.

### BRIEF DESCRIPTION OF THE DRAWINGS

FIG. 1 is a vertical sectional view illustrating a configuration example of a substrate processing apparatus according to an embodiment;

FIG. 2 is a plan view illustrating a configuration of the inside of a processing container of the substrate processing apparatus of FIG. 1;

FIG. 3 is a perspective view illustrating a configuration of a rotary table and mounting tables of the substrate processing apparatus of FIG. 1;

FIG. 4A is a plan view illustrating a rotation state of a rotary table and mounting tables of a substrate processing apparatus according to a reference example;

FIG. 4B is a view illustrating a state of a substrate on the mounting table according to the reference example;

FIG. 5A is a plan view illustrating the mounting table of the substrate processing apparatus according to the embodiment;

FIG. 5B is a cross-sectional view taken along line VB-VB in FIG. 5A;

FIG. 6A is a plan view illustrating a rotation state of the rotary table and the mounting tables of the substrate processing apparatus according to the embodiment;

FIG. 6B is a view illustrating a state of a substrate on the mounting table;

FIG. 7A is a table showing a relationship between a revolution speed of the rotary table and an axial rotation speed of the mounting table when a diameter φ of the mounting table is 302 mm;

FIG. 7B is a table showing a relationship between a revolution speed of the rotary table and an axial rotation speed of the mounting table when a diameter φ of the mounting table is 340 mm;

FIG. 8 is a flowchart of a substrate processing method according to an embodiment;

FIG. 9A is an enlarged plan view illustrating a mounting table according to a first modified example; and

FIG. 9B is an enlarged plan view illustrating a mounting table according to a second modified example.

### DETAILED DESCRIPTION

The present disclosure provides a technique capable of suppressing particles.

Hereinafter, embodiments for implementing the present disclosure will be described with reference to the drawings. In the drawings, the same components are denoted by the same reference numerals, and a duplicate description thereof may be omitted.

### (Basic Configuration of Substrate Processing Apparatus)

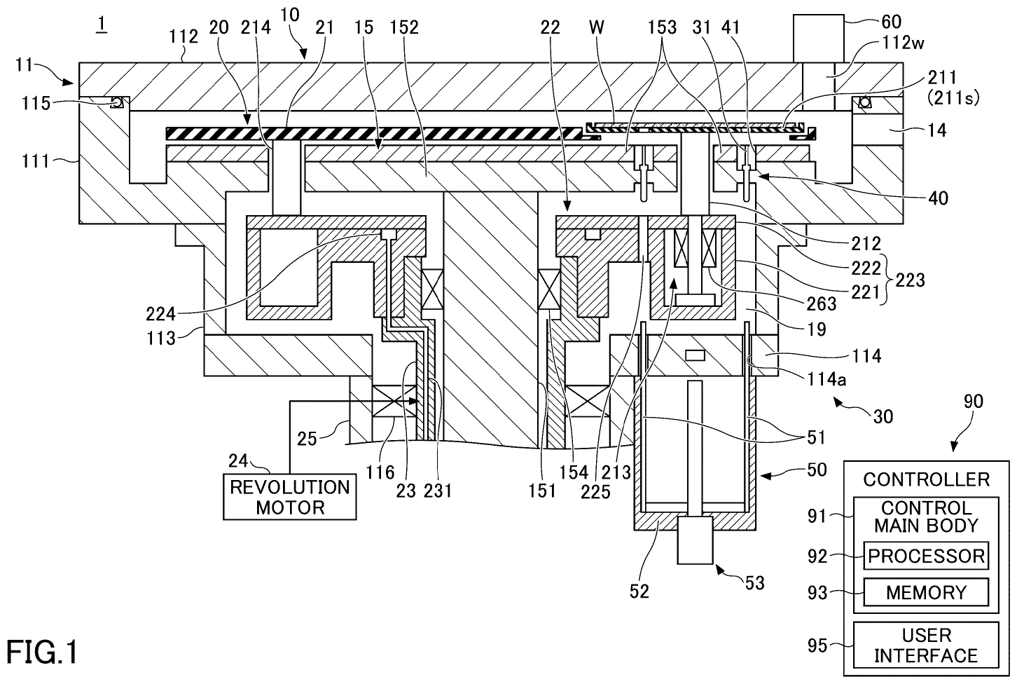

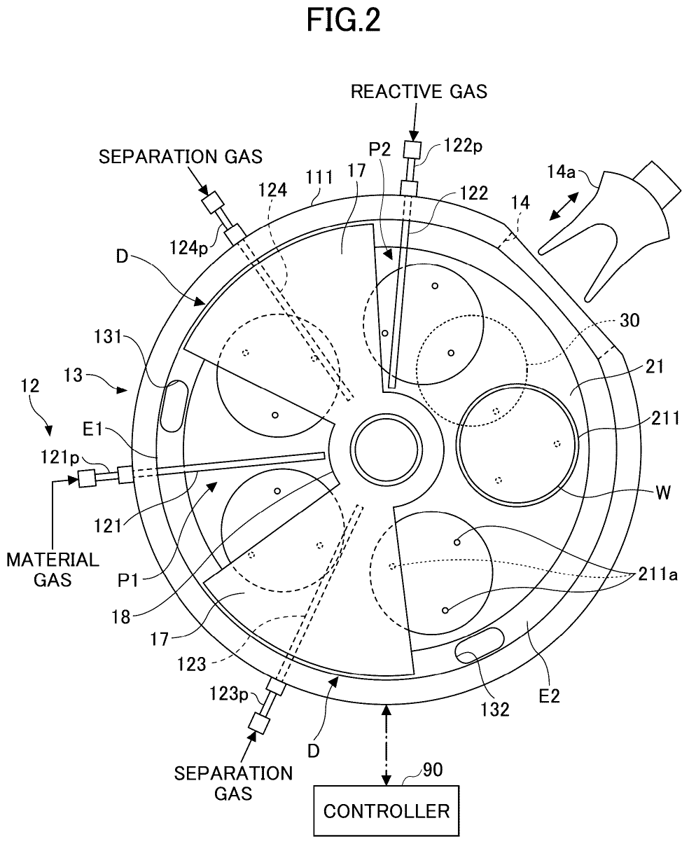

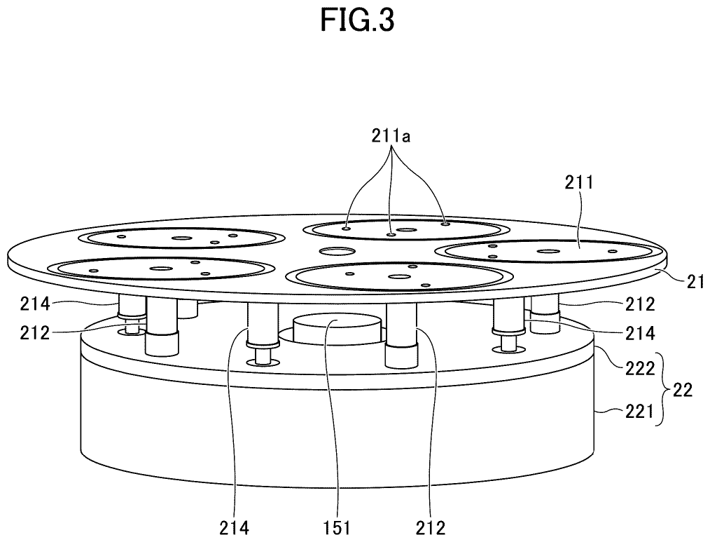

A substrate processing apparatus 1 according to an embodiment will be described with reference to FIGS. 1 through 3. FIG. 1 is a vertical sectional view illustrating a configuration example of the substrate processing apparatus 1 according to the embodiment. FIG. 2 is a plan view illustrating a configuration of the inside of a processing container 11 of the substrate processing apparatus 1 of FIG. 1. In FIG. 2, the top plate is not illustrated for convenience of explanation. FIG. 3 is a perspective view illustrating a configuration of a rotary table 21 and mounting tables 211 of the substrate processing apparatus 1 of FIG. 1.

The substrate processing apparatus 1 is configured as an apparatus that performs film forming processing of forming a film on a surface of a substrate W by an atomic layer deposition (ALD) method or a molecular layer deposition (MLD) method. The substrate processing apparatus 1 includes a processor 10, a rotation driving device 20, a lifter 30, and a controller 90.

The processor 10 performs film formation processing of forming a film on a substrate W. The processor 10 includes a processing container 11, a gas introduction part 12, a gas exhaust part 13, a transfer port 14, and a heating part 15.

The processing container 11 is a vacuum container capable of switching its atmosphere to a vacuum atmosphere by decreasing the pressure of the internal space. The processing container 11 is formed in a flat housing having a substantially circular planar shape and can accommodate a plurality of substrates W in the internal space. A substrate W may be, for example, a semiconductor wafer. The processing container 11 includes a main body 111, a top plate 112, a side wall body 113, and a bottom plate 114 (FIG. 1). The main body 111 has a cylindrical shape. The top plate 112 is detachably attached to the upper surface of the main body 111. The main body 111 and the top plate 112 are airtightly in close contact with each other due to a sealing portion 115. The side wall body 113 has a cylindrical shape and is airtightly connected to the lower surface of the main body 111. The bottom plate 114 is airtightly connected to the bottom surface of the side wall body 113.

The gas introduction part 12 includes a material gas nozzle 121, a reactive gas nozzle 122, and separation gas nozzles 123 and 124 (FIG. 2). The material gas nozzle 121, the reactive gas nozzle 122, and the separation gas nozzles 123 and 124 are arranged above a rotary table 21 (to be described later) at intervals along the circumferential direction of the processing container 11. In the illustrated example, the separation gas nozzle 123, the material gas nozzle 121, the separation gas nozzle 124, and the reactive gas nozzle 122 are arranged in this order in a clockwise direction (the rotational direction of the rotary table 21) from the transfer port 14. The material gas nozzle 121, the reactive gas nozzle 122, and the separation gas nozzles 123 and 124 have gas introduction ports 121p, 122p, 123p, and 124p (FIG. 2) for introducing various gases at their base ends. The gas introduction ports 121p, 122p, 123p, and 124p are fixed to the side wall of the main body 111 and protrude to the outside of the main body 111. The material gas nozzle 121, the reactive gas nozzle 122, and the separation gas nozzles 123 and 124 are inserted into the processing container 11 from the side wall of the main body 111 and extend inward in the radial direction of the main body 111. The material gas nozzle 121, the reactive gas nozzle 122, and the separation gas nozzles 123 and 124 are formed of, for example, quartz, and are disposed parallel to the rotary table 21.

The material gas nozzle 121 is connected to a material gas supply source (not illustrated) via a pipe, a flow rate controller, and the like (not illustrated). As the material gas, for example, a silicon-containing gas or a metal-containing gas may be used. In the material gas nozzle 121, a plurality of discharge holes (not illustrated) opened toward the rotary table 21 are arranged at intervals along the axial direction of the material gas nozzle 121. A region below the material gas nozzle 121 serves as a material gas adsorbing region P1 for adsorbing a material gas onto a substrate W.

The reactive gas nozzle 122 is connected to a reactive gas supply source (not illustrated) via a pipe, a flow rate controller, and the like (not illustrated). As the reactive gas, for example, an oxidizing gas or a nitriding gas can be used. In the reactive gas nozzle 122, a plurality of discharge holes (not illustrated) opened toward the rotary table 21 are arranged at intervals along the axial direction of the reactive gas nozzle 122. A region below the reactive gas nozzle 122 is a reactive gas supplying region P2 where a material gas adsorbed on a substrate W in the material gas adsorbing region P1 is oxidized or nitrided. In the present embodiment, the processing gas for processing a substrate W corresponds to the above-described material gas and reactant gas.

The separation gas nozzles 123 and 124 are connected to a separation gas supply source (not illustrated) via a pipe and a flow rate control valve (not illustrated). As the separation gas, for example, an inert gas such as argon (Ar) gas or nitrogen gas (N₂) can be used. In the separation gas nozzles 123 and 124, a plurality of discharge holes (not illustrated) opened toward the rotary table 21 are arranged at intervals along the axial direction of the separation gas nozzles 123 and 124.

As illustrated in FIG. 2, two projecting portions 17 are provided in the processing container 11. The projecting portion 17 is attached to the rear surface of the top plate 112 so as to protrude toward the rotary table 21 in order to constitute a separation region D together with the separation gas nozzles 123 and 124. Each projecting portion 17 has a fan-like planar shape with a vertex portion cut in an arc shape, and is arranged in such a manner that an inner arc is connected to the protrusion 18 and an outer arc is along the side wall of the processing container 11.

The gas exhaust part 13 includes a first exhaust port 131 and a second exhaust port 132 (FIG. 2). The first exhaust port 131 is formed at the bottom of a first exhaust region E1 communicating with the material gas adsorbing region P1. The second exhaust port 132 is formed at the bottom of a second exhaust region E2 communicating with the reactive gas adsorbing region P2. The first exhaust port 131 and the second exhaust port 132 are connected to an exhaust device (not illustrated) via an exhaust pipe (not illustrated).

The transfer port 14 is provided in a side wall of the main body 111 (FIG. 2). At the transfer port 14, a substrate W is transferred between the rotary table 21 in the processing container 11 and the transfer device 14a outside the processing container 11. The transfer port 14 is opened and closed by a gate valve (not illustrated).

The heating part 15 includes a fixing shaft 151, a heater support portion 152, and a heater 153 (FIG. 1). The substrate processing apparatus 1 may include a cooling part for cooling a substrate W instead of (or in addition to) the heating part 15.

The fixing shaft 151 has a cylindrical shape having a central axis at the center of the processing container 11. The fixing shaft 151 penetrates the bottom plate 114 of the processing container 11 inside a rotation shaft 23 of the rotation driving device 20, which will be described later.

The rotation driving device 20 includes the rotary table 21, an accommodation box 22, the rotation shaft 23, a revolution motor 24, and an outer cylinder 25.

The rotary table 21 is provided in the processing container 11 and has a rotation center at the center of the processing container 11. The rotary table 21 has, for example, a disk shape and is made of quartz. A plurality of (e.g., five) mounting tables 211 are provided on the upper surface of the rotary table 21 along the rotational direction (circumferential direction). The rotary table 21 is connected to the accommodation box 22 via a connecting portion 214 (FIG. 3).

Each of the mounting tables 211 has a disk shape slightly larger than a substrate W and is made of, for example, quartz. Each of the mounting tables 211 is connected to an axial rotation motor 213 via an axial rotation shaft 212 and is configured to be rotatable with respect to the rotary table 21 (FIG. 1).

The axial rotation shaft 212 connects the lower surface of the mounting table 211 to the axial rotation motor 213 accommodated in the accommodation box 22, and transmits the power of the axial rotation motor 213 to the mounting table 211. The axial rotation shaft 212 is configured to be rotatable about the center of the mounting table 211 serving as a rotation center. The axial rotation shaft 212 is provided to penetrate a ceiling portion 222 of the accommodation box 22 and the rotary table 21. A sealing portion 263 is provided in the vicinity of the penetrated portion in the ceiling portion 222 of the accommodation box 22, so that an airtight state in the accommodation box 22 is maintained. The sealing portion 263 includes, for example, a magnetic fluid seal.

The axial rotation motor 213 rotates the mounting table 211 relative to the rotary table 21 via the axial rotation shaft 212, thereby causing a substrate W to axially rotate about the center of the substrate W. It is preferable to apply, for example, a servo motor to the axial rotation motor 213.

The connecting portion 214 connects the lower surface of the rotary table 21 and the upper surface of the accommodation box 22 (FIG. 3). A plurality of the connecting portions 214 are provided along the circumferential direction of the rotary table 21.

The accommodation box 22 is provided below the rotary table 21 in the processing container 11. The accommodation box 22 is connected to the rotary table 21 via the connecting portion 214 and rotates integrally with the rotary table 21. The accommodation box 22 may be configured to be elevatable and lowerable in the processing container 11 by an elevating mechanism (not illustrated). The accommodation box 22 includes a main body portion 221 and the ceiling portion 222.

The main body portion 221 is formed in a concave shape in a vertical cross-sectional view, and is formed in a ring shape along the rotation direction of the rotary table 21 (FIG. 1)

The ceiling portion 222 is provided on the upper surface of the main body portion 221 so as to cover the opening of the main body portion 221. Thus, the main body 221 and the ceiling portion 222 form a rotary accommodation part 223 isolated from the inside of the processing container 11.

The rotary accommodation part 223 is formed in a rectangular shape in a vertical sectional view and has a ring shape along the rotation direction of the rotary table 21. The rotary accommodation part 223 accommodates the axial rotation motor 213 (rotation source). A communication passage 224 that allows the rotary accommodation part 223 to communicate with the outside of the substrate processing apparatus 1 is formed in the main body 221. Thus, the air is introduced into the rotary accommodation part 223 from the outside of the substrate processing apparatus 1, and the inside of the rotary accommodation part 223 is cooled and maintained at atmospheric pressure. In order to rotatably arrange the rotary accommodation part 223, the processing container 11 has a rotation source accommodation space 19 surrounded by the side wall body 113, the bottom plate 114, and the heating part 15.

The rotation shaft 23 is fixed to a lower portion of the accommodation box 22. The rotation shaft 23 is provided to penetrate the bottom plate 114 of the processing container 11. The rotation shaft 23 transmits the power of the revolution motor 24 to the rotary table 21 and the accommodation box 22, and integrally rotates the rotary table 21 and the accommodation box 22. A sealing portion 154 is provided between an outer wall of the fixing shaft 151 and an inner wall of the rotation shaft 23 of the rotation driving device 20. Thus, the rotation shaft 23 rotates with respect to the fixing shaft 151 while maintaining an airtight state in the processing container 11. For example, a magnetic fluid seal can be applied to the sealing portion 154.

An outer cylinder 25 of the rotation driving device 20 is connected to a lower surface portion of the bottom plate 114 of the processing container 11 on the center region. The outer cylinder 25 supports the processing container 11 together with the fixing shaft 151 of the processing container 11. A sealing portion 116 is provided between the rotation shaft 23 and the outer cylinder 25, and an airtight state in the processing container 11 is maintained. For example, a magnetic fluid seal can be applied to the sealing portion 116.

A passage 231 is formed inside the rotation shaft 23. The passage 231 is connected to a communication passage 224 of the accommodation box 22 and functions as a fluid flow path for introducing the atmosphere into the accommodation box 22. The passage 231 also functions as a wiring duct for introducing a power line and a signal line for driving the axial rotation motor 213 into the accommodation box 22. The number of the passages 231 is the same as the number of the axial rotation motors 213, for example.

As illustrated in FIG. 1, when the transfer device 14a (FIG. 2) loads and unloads a substrate W into and from the mounting table 211, the lifter 30 elevates and lowers a plurality of (three in the present embodiment) lift pins 31 to receive and deliver the substrate W from and to the transfer device 14a. In the substrate processing apparatus 1, the lifter 30 is installed in the lower side of the vertical direction below a position facing the mounting table adjacent to the transfer port 14. In the processing container 11, the lifter 30 includes a plurality of (three) upper structure parts 40 having respective lift pins 31 and one lower operation part 50 configured to simultaneously elevate and lower the plurality of lift pins 31.

Each upper structure part 40 is installed to penetrate the heater support portion 152 and the heater 153, and accommodates the lift pin 31 in a displaceable manner. The lower operation part 50 is attached to the lower surface of the bottom plate 114 of the processing container 11. The lower operation part 50 includes a plurality of (three) plungers 51 that are displaced along the vertical direction to press the lower ends 32 of the lift pins 31, respectively. In other words, the lifter 30 has a two-stage structure in which the plurality of lift pins 31 that come into contact with a substrate W and the plurality of plungers 51 that indirectly elevate and lower a substrate W via the lift pins 31 are provided separately in the vertical direction as operating members.

The lower operation part 50 includes a case 52 and a plunger driver 53 in addition to the plungers 51. Each plunger 51 is formed in a long and thin solid rod shape, and is moved in the rotation source accommodation space 19 by the plunger driver 53. The lifter 30 pushes up the lift pin 31 by coming into contact with the lift pin 31 of each upper structure part 40 as each plunger 51 rises.

Each upper structure part 40 is provided at a position spaced apart from the axial rotation shaft 212 in the radial direction and along the circumferential direction of the mounting table 211. Each upper structure part 40 supports the lift pin 31 so as not to fall off downward in the vertical direction. The mounting table 211 includes a plurality of (three) through-holes 211a through which the lift pins 31 can pass, corresponding to the arrangement positions of the upper structure part 40 (see also FIG. 2). The lift pin 31 is a columnar member extending linearly, and is raised by the lower end being pushed up by the raised plunger 51. Thus, the upper end of the lift pin 31 protrudes from the upper surface of the mounting table 211 through the through-hole 211a of the mounting table 211.

Returning to FIG. 1, the controller 90 is configured to control each part of the substrate processing apparatus 1. The controller 90 includes a control main body 91 and a user interface 95. The control main body 91 is a computer including a processor 92, a memory 93, an input/output interface (not illustrated), and a communication interface (not illustrated). The one or more processors 92 are one of or a combination of a central processing unit (CPU), a graphics processing unit (GPU), an application specific integrated circuit (ASIC), a field-programmable gate array (FPGA), a circuit including a plurality of discrete semiconductors, and the like. The memory 93 includes a main storage device including a semiconductor memory or the like, and an auxiliary storage device including a disk, a semiconductor memory (flash memory), or the like. In other words, in the present disclosure, the controller 90 is an electronic circuit including a CPU, a GPU, an ASIC, an FPGA, or the like, and executes various control operations described in the present specification by executing instruction codes stored in the memory 93 or by designing a circuit for a special purpose.

The user interface 95 is connected to the input/output interface of the control main body 91. The user interface 95 is not particularly limited, and examples thereof include a touch panel, a monitor, a keyboard, and a mouse.

The substrate processing apparatus 1 configured as described above rotates the rotary table 21 (revolution) and rotates each of the plurality of mounting tables 211 (axial rotation), with a substrate W being mounted on each of the plurality of mounting tables 211 of the rotary table 21. The substrate processing apparatus 1 performs substrate processing on each substrate W by supplying a processing gas from the gas introduction part 12 into the processing container 11 during revolution and axial rotation of each substrate W.

### (Generation of Particles During Substrate Processing)

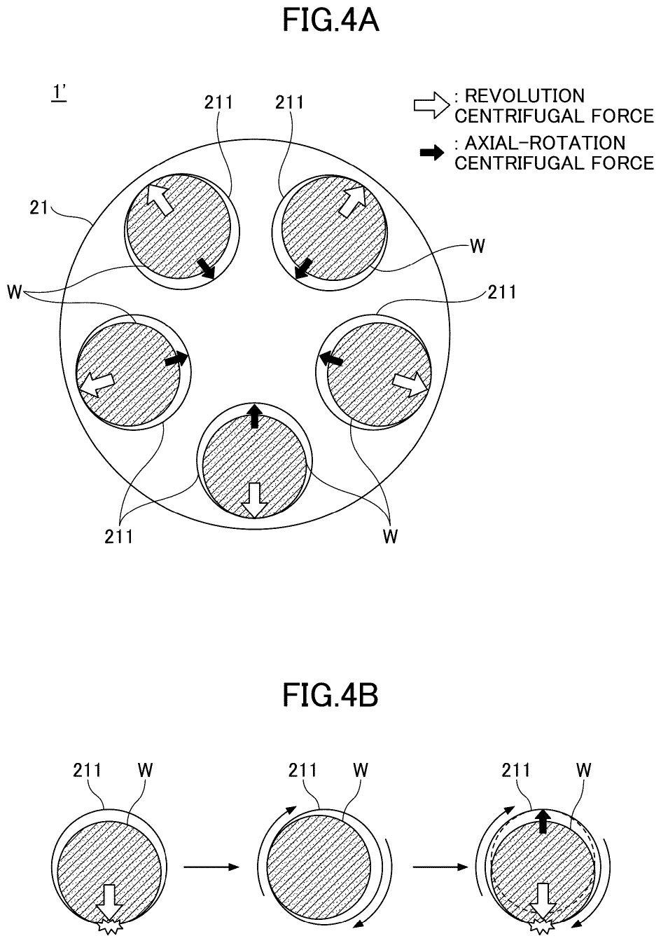

In the configuration in which each substrate W is revolved and axially rotated during substrate processing, each substrate W receiving centrifugal force during rotation moves in the mounting table. Hereinafter, for ease of understanding of the present disclosure, a substrate processing apparatus 1′ according to a reference example will be described with reference to FIGS. 4A and 4B. FIG. 4A is a plan view illustrating a rotation state of the rotary table 21 and the mounting tables 211 of the substrate processing apparatus 1′ according to the reference example. FIG. 4B is a view illustrating a state of a substrate W on the mounting table 211 according to the reference example.

As illustrated in FIG. 4A, each substrate W mounted on each mounting table 211 of the rotary table 21 receives a centrifugal force in accordance with the rotation of the rotary table 21. Hereinafter, the centrifugal force generated by the rotation of the rotary table 21 is also referred to as a “revolution centrifugal force”. Each substrate W on each mounting table 211 also receives a centrifugal force generated by the rotation of the mounting table 211. Hereinafter, the centrifugal force generated by the rotation of each mounting table 211 is also referred to as an “axial-rotation centrifugal force”. However, in substrate processing apparatus 1′ according to the reference example, the axial rotation speed of each mounting table 211 is significantly slower than the revolution speed of the rotary table 21 in substrate processing. For example, in substrate processing according to the reference example, the rotation speed of the rotary table 21 is set to 60 rpm (rotations per minute), and the rotation speed of each mounting table 211 is set to 5.5 rpm.

Therefore, the substrate processing apparatus 1′ according to the reference example applies a force having a relationship of the revolution centrifugal force being greater than the axial-rotation centrifugal force to each substrate W during the substrate processing. In this case, as illustrated in the left diagram of FIG. 4B, each substrate W receives a revolving centrifugal force outward in a radial direction from the rotary table 21, and thus moves outward in a radial direction of the rotary table 21 against a frictional force in each mounting table 211. For example, the substrate W moves in the mounting table 211 and comes into contact with an inner peripheral surface surrounding the mounting table 211. As illustrated in the middle diagram of FIG. 4B, the substrate W that has moved to the inner peripheral surface circulates in the mounting table 211 along with the rotation of the mounting table 211. Then, for example, as illustrated in the right diagram of FIG. 4B, the substrate W receives a revolution centrifugal force at a position moved toward the rotation center of the rotary table 21, and thus the substrate W moves outward in a radial direction in the mounting table 211 and once again comes into contact with the inner peripheral surface on the radially outer side. Since the substrate W repetitively moves in the mounting table 211 in the substrate processing apparatus 1′ according to the reference example, the chance of the substrate W being rubbed or colliding when moving increases, and particles are generated.

### (Configuration for Suppressing Particles)

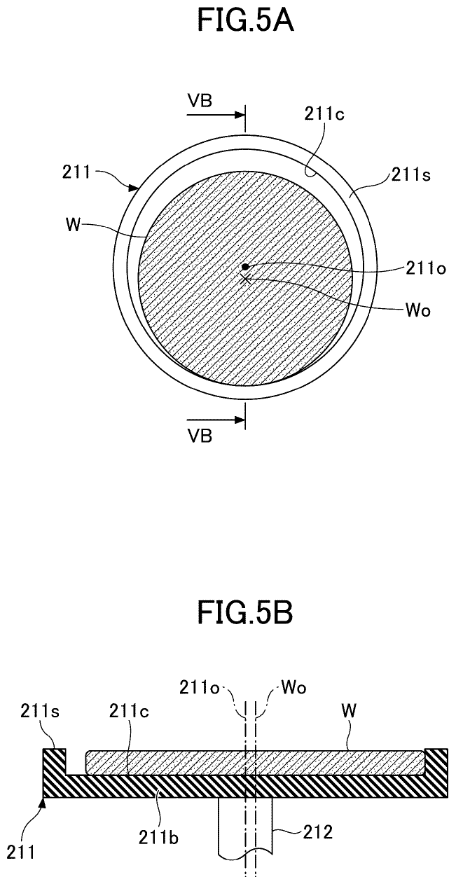

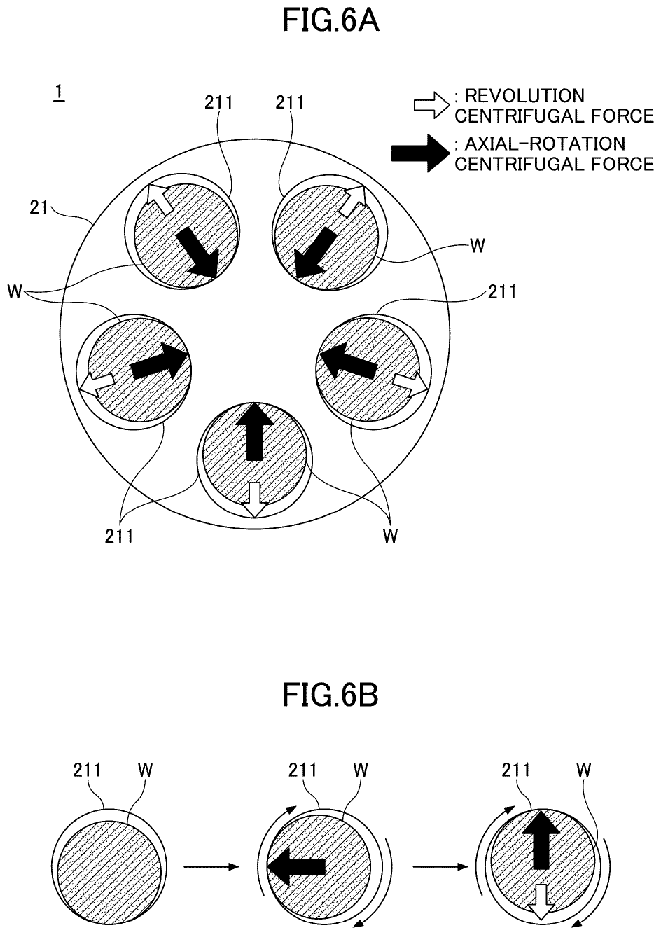

FIG. 5A is a plan view illustrating the mounting table 211 of the substrate processing apparatus 1 according to the embodiment. FIG. 5B is a cross-sectional view taken along line VB-VB in FIG. 5A. FIG. 6A is a plan view illustrating a rotation state of the rotary table 21 and the mounting tables 211 of the substrate processing apparatus 1 according to the embodiment. FIG. 6B is a view illustrating a state of a substrate W on the mounting table 211. In the substrate processing apparatus 1 according to the embodiment, each of the mounting tables 211 is formed in a concave shape as illustrated in FIGS. 5A and 5B, and the axial-rotation centrifugal force is larger than the revolution centrifugal force as illustrated in FIGS. 6A and 6B.

Specifically, the mounting table 211 has a bottom surface 211b on which a substrate W is mounted and a side wall 211s protruding from an outer edge of the bottom surface 211b. The bottom surface 211b and the side wall 211s form a recess 211c in the inside of the bottom surface 211b and the side wall 211s. The side wall 211s is formed in a circular annular shape in a plan view. The height of the side wall 211s is not particularly limited, but is preferably set to be equal to or greater than the width of a substrate W. The mounting table 211 is configured to be rotated around a center 211o by the axial rotation shaft 212 connected to the center 211o. In the embodiment, the center 211o of the outer shape (the outer peripheral surface of the side wall 211s) of the mounting table 211 coincides with the center of the recess 211c.

When a substrate W mounted in the recess 211c of the mounting table 211 moves in the plane direction of the bottom surface 211b by receiving a centrifugal force, the substrate W comes into contact with the side wall 211s. FIGS. 5A and 5B illustrate a state in which a substrate W is in contact with the side wall 211s. The substrate W in contact with the side wall 211s is restricted from further movement by the side wall 211s even if the substrate W receives a centrifugal force, and is prevented from coming off of the mounting table 211 by the side wall 211s. Thus, the center Wo of the substrate W rotates in a state of being shifted from the center 211o of the mounting table 211. When the axial-rotation centrifugal force is larger than the revolution centrifugal force, the rotation of the mounting table 211 is continued while the substrate W is in contact with the side wall 211s. In other words, the repetition of the movement of each substrate W in each mounting table 211 as illustrated in FIG. 4B is eliminated.

Specifically, as illustrated in FIG. 6A, the substrate processing apparatus 1 controls the rotation of the rotary table 21 and the rotation of each mounting table 211 by the controller 90 to establish the relationship of the revolution centrifugal force being less than the axial-rotation centrifugal force. As described above, when the axial-rotation centrifugal force is larger than the revolution centrifugal force, the substrate W once comes into contact with the side wall 211s of the mounting table 211 and then starts to integrally rotate with the mounting table 211.

In other words, as illustrated in the left diagram of FIG. 6B, the substrate W moves to the outer side in the radial direction of the rotary table 21 in the recess 211c of the mounting table 211 and comes into contact with the side wall 211s. The substrate W that has moved to the side wall 211s receives an axial-rotation centrifugal force larger than the revolution centrifugal force caused by the rotation of the mounting table 211. Thus, even in the case where the substrate W moves in the tangential direction of the rotation direction of the rotary table 21 illustrated in the middle diagram of FIG. 6B or moves toward the center of the rotary table 21 illustrated in the right diagram of FIG. 6B, the substrate W comes to keep the position. In other words, the substrate processing apparatus 1 substantially fixes the substrate W in the mounting table 211 so as to prevent the substrate W from repetitively moving, using the relationship of the revolution centrifugal force being less than the axial-rotation centrifugal force. By reducing the chance of the substrate W moving in the mounting table 211 in this way, the substrate processing apparatus 1 can suppress generation of particles.

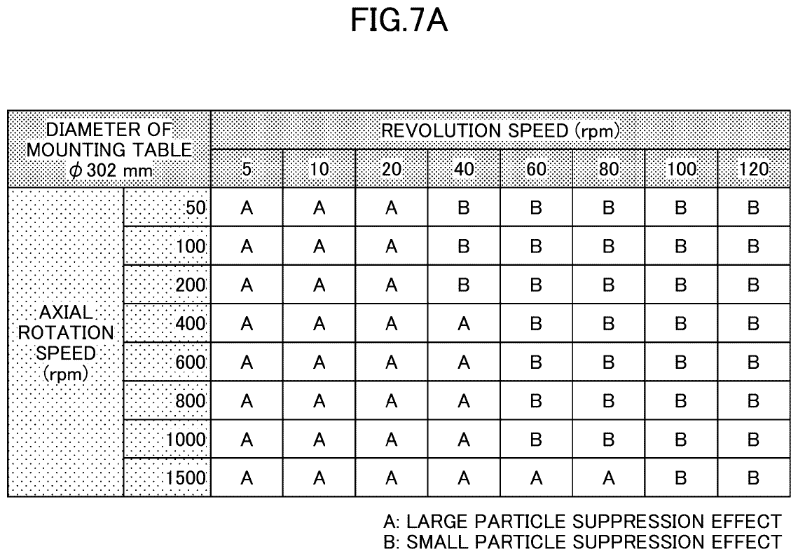

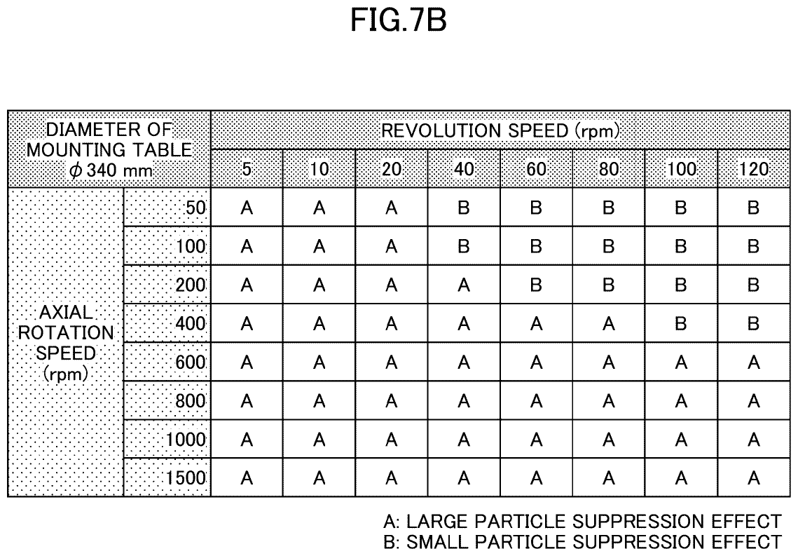

Next, setting of various parameters for establishing the relationship of the revolution centrifugal force being less than the axial-rotation centrifugal force is described, with reference to FIGS. 7A and 7B. FIG. 7A is a table showing a relationship between a revolution speed of the rotary table 21 and an axial rotation speed of the mounting table 211 when the diameter φ of the mounting table 211 is 302 mm (millimeters). FIG. 7B is a table showing a relationship between a revolution speed of the rotary table 21 and an axial rotation speed of the mounting table 211 when the diameter φ of the mounting table 211 is 340 mm (millimeters). The diameter φ of the mounting table 211 is the length of a line passing through the center 211o of the mounting table 211 from the inner peripheral surface of the side wall 211s to the inner peripheral surface of the side wall 211s, in other words, twice the radius of the recess 211c from the center 211o to the side wall 211s.

The centrifugal force of a rotating object generated by rotation is generally expressed by the following Expression (1).

F=mω²r (1)

In Expression (1), m is a mass of a rotating object, ω is a rotation speed during rotation, and r is a radius of rotation.

Therefore, the revolution centrifugal force F₁ received by a substrate W mounted on each of the mounting tables 211 from the rotary table 21 can be expressed by the following Expression (2) in the case where the revolution speed is ω₁ and the radius of rotation from the rotation center of the rotary table 21 to the center Wo of each substrate W is r₁.

F₁=mω₁²r₁ (2)

In Expression (2), m is a mass of the substrate W. The radius of rotation r₁ can be approximated to a length from the rotation center of the rotary table 21 to the center 211o of the mounting table 211.

On the other hand, the axial-rotation centrifugal force F₂ received by a substrate W that has moved to the side wall 211s from the mounting table 211 can be expressed by the following Expression (3), where ω₂ is an axial rotation speed of rotation and r₂ is a radius of rotation from the center 211o of the mounting table 211 to the center Wo of the substrate W.

F₂=mω²r₂ (3)

In Expression (2), m is a mass of the substrate W.

Therefore, in order to establish the relationship of the revolution centrifugal force F₁ being less than the axial-rotation centrifugal force F₂, the respective parameters may be set so as to satisfy ω₁²r₁<ω₂²r₂. However, the radius of rotation r₁ among the parameters of the revolution centrifugal force depends on the number of the mounting tables 211 installed on the rotary table 21, the size of the rotary table 21, and the like. In other words, although the radius of rotation r₁ is preferably as small as possible, in the case where the radius of rotation r₁ is small, the size of the rotary table 21 is reduced so as to reduce the number of the mounting tables 211 to be installed. In this case, the number of substrates W processed in one session of substrate processing is reduced. On the other hand, the radius of rotation r₂ among the parameters of the axial-rotation centrifugal force is determined depending on the diameter φ of the mounting tables 211, and further, the number of the mounting tables 211 installed on the rotary table 21 is also influenced. In other words, although the radius of rotation r₂ is preferably as large as possible, in the case where the radius of rotation r₂ is large, the mounting tables 211 adjacent to each other in the circumferential direction may overlap each other, and thus the number of mounting tables 211 to be installed is also reduced. Therefore, also in this case, the number of substrates W processed in one session of substrate processing is reduced.

In consideration of the above-described matters, it is preferable to set first the size of the rotary table 21 and the number of the mounting tables 211 mounted on the rotary table 21, and then the radii of rotation r₁ and r₂. The diameter φ of the mounting table 211 in FIG. 7A is 302 mm, and the radius of rotation r₂ is 1 mm in the case where the diameter of the substrate W is 300 mm. The diameter φ of the mounting table 211 in FIG. 7B is 340 mm, and the radius of rotation r₂ is 20 mm in the case where the diameter of the substrate W is 300 mm. As illustrated in FIGS. 7A and 7B, for a larger diameter φ of the mounting table 211, the range of the revolution speed and the axial rotation speed that achieves a large particle suppression effect is wider (i.e., there are more cells indicated with A). In other words, the relationship of the revolution centrifugal force being less than the axial-rotation centrifugal force can be easily established for the case where the mounting table 211 has a larger diameter φ (i.e., a large radius of rotation r₂) for the same revolution speed and the same axial rotation speed.

However, as described above, when the diameter φ (the radius of rotation r₂) of the mounting tables 211 is excessively increased, the mounting tables 211 adjacent to each other in the circumferential direction may overlap each other. For example, when five mounting tables 211 are installed on the rotary table 21, the range of the diameter φ of the mounting tables 211 is preferably set to a range of about 302 mm to 350 mm. When five mounting tables 211 are installed on the rotary table 21, the relationship between the radius of rotation r₁ of the rotary table 21 and the radius of rotation r₂ of the mounting table 211 is preferably set to satisfy r₁/10≥r₂. By setting the radii of rotation r₁ and r₂ based on the size of the rotary table 21 and the number of the mounting tables 211, the diameter φ (the radius of rotation r₂) of the mounting tables 211 can be appropriately designed without causing overlaps of the mounting tables 211. The number of the mounting tables 211 is not particularly limited, and may be four or less, or six or more.

The relationship between the revolution speed ω₁ and the axial rotation speed ω₂, which satisfies the revolution centrifugal force being less than the axial-rotation centrifugal force, is simply ω₁<ω₂. However, in the case where a user wants to fix the substrates W more reliably, it is desirable to set the axial-rotation centrifugal force to be larger to some extent than the revolution centrifugal force. Therefore, as the relationship between the revolution speed ω₁ and the axial rotation speed ω₂ in which the particle suppression effect can be sufficiently obtained, it is preferable that the axial rotation speed ω₂ is 2.5 times or more the revolution speed ω₁ (i.e., 2.5×ω₁≤ω₂). Thus, the substrate processing apparatus 1 can sufficiently increase the axial-rotation centrifugal force.

In the substrate processing (film formation processing), as the revolution speed and/or the axial rotation speed increases, the efficiency of the substrate processing improves, but the quality of the film formed on each substrate W tends to deteriorate. Therefore, it is preferable that the revolution speed and the axial rotation speed are appropriately selected in consideration of the efficiency of the substrate processing, the film quality of each substrate W, the effect of suppressing the particles as shown in FIGS. 7A and 7B, and the like.

As an example, when the efficiency of the substrate processing is considered to be important, the revolution speed is preferably set to be equal to or higher than 40 rpm. The axial rotation speed is preferably set to be 10 times or more the revolution speed. Thus, the substrate W can be fixed to each mounting table 211 while the substrate processing is performed in a short time, and the effect of suppressing particles can be enhanced. In particular, when the radius of rotation r₂ is increased by setting the diameter φ of the mounting table 211 to 340 mm, the revolution speed is set to be equal to or higher than 120 rpm, and the axial rotation speed is set to be equal to or higher than 600 rpm, the substrate processing can be performed in a shorter time.

On the other hand, when the quality (film quality) of the substrate processing is considered to be important, the revolution speed is preferably set to be equal to or lower than 20 rpm. As shown in FIGS. 7A and 7B, as long as the revolution speed is equal to or lower than 20 rpm, the particle suppression effect can be enhanced even when the axial rotation speed is any value equal to or higher than 50 rpm.

### (Substrate Processing Method)

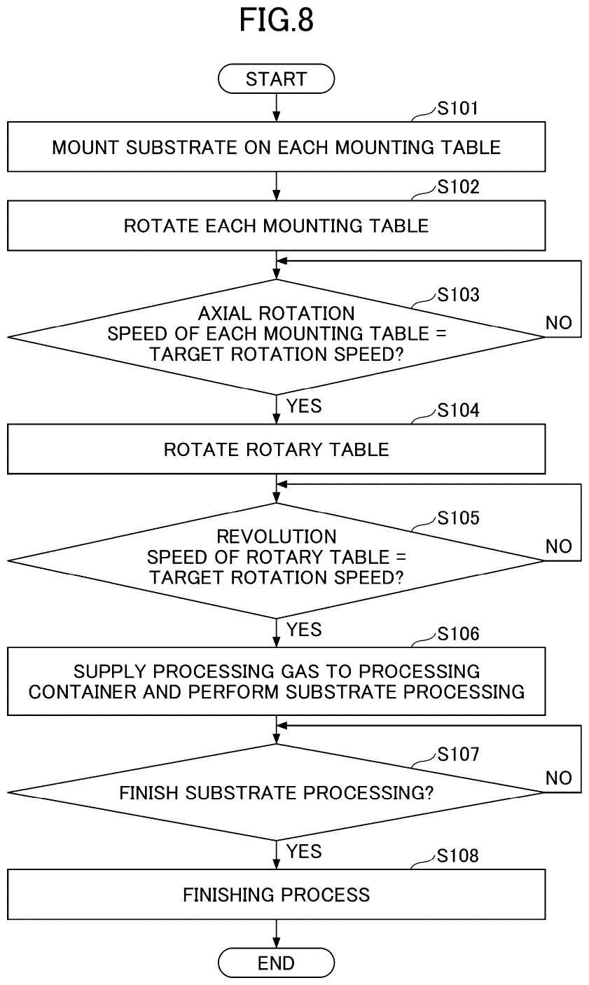

The substrate processing apparatus 1 according to the embodiment is basically configured as described above, and the operation (substrate processing method) thereof will be described below with reference to FIG. 8. FIG. 8 is a flowchart of the substrate processing method according to the embodiment.

The controller 90 of the substrate processing apparatus 1 controls steps S101 to S108 illustrated in FIG. 8 in the substrate processing method to perform, for example, substrate processing (film formation processing) for forming a desired film on a substrate W.

The controller 90 controls the substrate processing apparatus 1 and the transfer device 14a to sequentially mount a substrate W on each of five mounting tables 211 of the rotary table 21 (step S101). At this time, the substrate processing apparatus 1 rotates the rotary table 21 in such a manner that the center Wo of the substrate W coincides with the center 211o of the mounting table 211, and the transfer device 14a transfers the substrate W to a position directly above the mounting table 211. The lifter 30 receives the substrate W from the transfer device 14a by raising the lift pins 31, and mounts the substrate W on the recess 211c of the mounting table 211 by lowering the lift pins 31 after the transfer device 14a is withdrawn.

After the substrates W are respectively mounted on the mounting tables 211, the controller 90 starts rotation of the axial rotation motors 213 to rotate the mounting tables 211 on which the substrates W are respectively mounted (step S102). The controller 90 sets, before the substrate processing is performed, a target rotation speed of each mounting table 211, which is an axial rotation speed at which the effect of suppressing particles is large, automatically or based on a user input.

Then, the controller 90 determines whether or not the actual axial rotation speed of each mounting table 211 has reached the target rotation speed (step S103). In the case where the axial rotation speed has reached the target rotation speed (Yes in step S103), the process proceeds to step S104; in the case where the axial rotation speed has not reached the target rotation speed (No in step S103), the monitoring in step S103 is repeated.

Next, the controller 90 starts rotation of the revolution motor 24 to rotate the rotary table 21 (step S104). The controller 90 also sets the target rotation speed of the rotary table 21 automatically or based on a user input before the substrate processing is performed. The target rotation speed of the rotary table 21 is also set in correspondence with the revolution speed at which the particle suppression effect is large as described above.

When the revolution speed of the rotary table 21 increases, each substrate W in each mounting table 211 moves outward in the radial direction of the rotary table 21 and comes into contact with the side wall 211s. However, since the relationship of the revolution centrifugal force being less than the axial-rotation centrifugal force holds true, each substrate W once comes into contact with the side wall 211s and then follows the rotation of the mounting table 211, keeping its position. Thus, the substrates W are prevented from repeatedly moving in the respective mounting tables 211, and generation of particles is suppressed.

Then, the controller 90 determines whether or not the actual revolution speed of each mounting table 21 has reached the target rotation speed (step S105). In the case where the revolution rotation speed has reached the target rotation speed (Yes in step S105), the process proceeds to step S106; in the case where the revolution rotation speed has not reached the target rotation speed (No in step S105), the monitoring in step S105 is repeated.

By performing the substrate processing up to step S105, the rotary table 21 and the mounting tables 211 are simultaneously rotated in the substrate processing apparatus 1. In this process, the controller 90 supplies a processing gas to the processing container 11 by the gas introduction part 12 and performs substrate processing (film formation processing) on each substrate W (step S106). Also during the substrate processing, the rotary table 21 maintains the revolution speed as the target rotation speed, and each mounting table 211 maintains the axial rotation speed as the target rotation speed. In other words, the relationship in which the axial-rotation centrifugal force is larger than the revolution centrifugal force is maintained, and the movement of each substrate W on each mounting table 211 can be regulated, the generation of particles can be suppressed.

While the above-described substrate processing is being performed, the controller 90 determines whether or not to end the substrate processing (step S107). For example, the controller 90 monitors whether or not a target period of the substrate processing that is set by a recipe or the like has elapsed, and determines to end the substrate processing in the case where the target period has elapsed. The controller 90 proceeds to step S107 in the case where the substrate processing is to be terminated (Yes in step S108), and continues the substrate processing and repeats the monitoring when the substrate processing is not to be ended (No in step S107).

Finally, the controller 90 stops the supply of the processing gas, stops the rotation of the rotary table 21 and the rotation of the mounting tables 211, and performs an end process, such as taking out the substrates W from the respective rotary tables 21, thereby ending the current substrate processing (step S108).

As described above, with the substrate processing method, the movement of the substrate W in each mounting table 211 can be reduced, as long as the axial-rotation centrifugal force is larger than the revolution centrifugal force applied to the substrate W. As a result, the substrate processing method can suppress particles from being generated on the substrate W in each mounting table 211.

### MODIFIED EXAMPLES

The substrate processing apparatus 1 and the substrate processing method according to the present disclosure are not limited to the above-described embodiment, and various modifications may be made. For example, in the substrate processing method of FIG. 8, the mounting tables 211 are rotated before the rotary table 21 is rotated in order to apply an axial-rotation centrifugal force to the substrates W. However, in the substrate processing method, the rotary table 21 may be rotated before the mounting tables 211 are rotated. Alternatively, in the substrate processing method, rotation of the rotary table 21 and rotation of the mounting tables 211 may be started simultaneously.

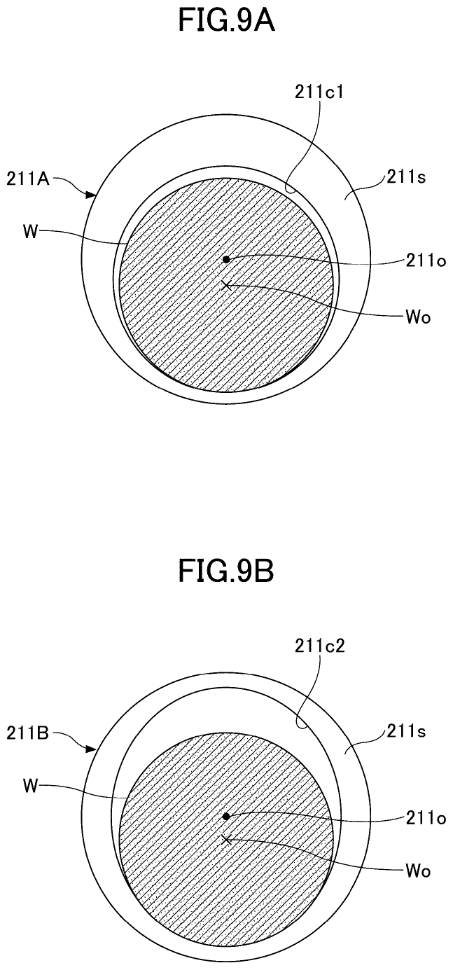

FIG. 9A is an enlarged plan view illustrating a mounting table 211A according to a first modified example. FIG. 9B is an enlarged plan view illustrating a mounting table 211B according to a second modified example. As illustrated in FIG. 9A, the mounting table 211A according to the first modified example differs from the mounting table 211 according to the embodiment in that the position of the recess 211c1 for accommodating the substrate W is shifted with respect to the outer shape of the entire mounting table 211A. Specifically, the mounting table 211A has a recess 211c1 having a perfect circle shape in a plan view. The side wall 211s surrounding the recess 211c1 is formed to be narrow on one side (lower side in FIG. 9A) and wide on the other side (upper side in FIG. 9A).

In the mounting table 211A configured as described above, the center 211o (rotation center) of the mounting table 211A and the center (not illustrated) of the recess 211c1 are arranged at positions shifted from each other in advance, and the diameter of the recess 211c can be reduced. Since the center of the recess 211c1 is shifted in advance, the substrate W mounted on the recess 211c1 easily receives the axial-rotation centrifugal force of the rotating mounting table 211A, and moves toward one side in the recess 211c1 for a short distance. The same applies to the case of receiving the revolution centrifugal force. In the substrate processing apparatus 1 having the mounting table 211A, the relationship of the revolution centrifugal force being less than the axial-rotation centrifugal force is established, and thus the substrate W can be easily fixed to one side and can be continuously rotated. Therefore, it is possible to expect an improvement in the effect of suppressing generation of particles.

As illustrated in FIG. 9B, the mounting table 211B according to the second modified example differs from the mounting tables 211 and 211A in that the entire mounting table 211B is formed in a perfect circle shape in a plan view but the recess 211c2 for accommodating the substrate W is formed in an elliptical shape in a plan view. The mounting table 211B having the recess 211c2 facilitates movement of the substrate W mounted in the recess 211c2 in the major axis direction of the elliptical shape. Thus, the substrate W can smoothly move to one end side of the long axis of the recess 211c1 when the substrate W receives a revolution centrifugal force. In the substrate processing apparatus 1 having the mounting table 211B, the relationship of the revolution centrifugal force being less than the axial-rotation centrifugal force is established, and thus the substrate W can be easily fixed to one end side of the long axis and can be continuously rotated. Therefore, in this case, it is also possible to expect an improvement in the effect of suppressing particles.

The technical idea and effects of the present disclosure described in the above embodiments will be described below.

The substrate processing apparatus 1 according to the first aspect of the present disclosure includes the processing container 11, the rotary table 21 rotatably provided inside the processing container 11, the mounting tables 211, 211A, or 211B for mounting a substrate thereon, the mounting tables 211, 211A, or 211B being configured to be integrally rotatable with the rotary table 21 and to be rotatable relative to the rotary table 21 at a position away from a rotation center of the rotary table 21, and the controller 90 configured to control rotation of the rotary table 21 and rotation of the mounting tables 211, 211A, or 211B, The controller 90 controls rotation of the rotary table 21 and rotation of the mounting tables 211, 211A, or 211B in such a manner that an axial-rotation centrifugal force generated by rotation of the mounting table 21 is larger than a revolution centrifugal force generated by rotation of the rotary table 211, 211A, or 211B.

According to the above description, the substrate processing apparatus 1 can suppress generation of particles by controlling the rotation of the rotary table 21 and the rotations of the mounting tables 211, 211A, or 211B in such a manner that the axial-rotation centrifugal force is larger than the revolution centrifugal force. In other words, the movement of the substrate W mounted on the mounting tables 211, 211A, or 211B is suppressed in the mounting tables 211, 211A, or 211B by the axial-rotation centrifugal force caused by the rotation of the mounting tables 211, 211A, or 211B. As a result, it is possible to suppress particles generated by the substrate being rubbed or colliding caused by the substrate moving.

The axial rotation speed of the mounting tables 211, 211A, or 211B is larger than the revolution speed of the rotary table 21. Thus, the substrate processing apparatus 1 can easily establish a relationship in which the axial-rotation centrifugal force is larger than the revolution centrifugal force, and can avoid an increase in cost required for suppressing generation of particles while suppressing generation of particles.

The axial rotation speed is 2.5 times or more the revolution speed. Thus, the substrate processing apparatus 1 can further increase the axial-rotation centrifugal force beyond the revolution centrifugal force, and can significantly suppress generation of particles.

The revolution speed is equal to or higher than 40 rpm, and the axial rotation speed is 10 times or more the revolution speed. Thus, the substrate processing apparatus 1 can sufficiently suppress particles during substrate processing while ensuring the efficiency of substrate processing on the substrate W.

Further, the radius of rotation r₂ from the rotation center of the mounting tables 211, 211A, or 211B to the center of the substrate W is equal to or less than 1/10 of the radius of rotation r₁ from the rotation center of the rotary table 21 to the rotation center of the mounting table 211. Thus, the substrate processing apparatus 1 can increase the number of the mounting tables 211, 211A, or 211B in the rotary table 21 while obtaining the axial-rotation centrifugal force of the mounting tables 211, 211A, or 211B.

The mounting tables 211, 211A, or 211B includes the recess 211c surrounded by the bottom surface 211b on which the substrate W is mounted and the side wall 211s projecting from the outer edge of the bottom surface 211b and to which the outer edge of the substrate W is contactable. Thus, the substrate processing apparatus 1 can suppress the movement of the substrate W by pressing the substrate W against the side wall 211s by the axial-rotation centrifugal force after the substrate W comes into contact with the side wall 211s in the mounting tables 211, 211A, or 211B.

The recess 211c is formed in a perfect circle shape in a plan view, and a center of the recess 211c and a rotation center of the mounting table 211A are shifted from each other. Thus, the substrate processing apparatus 1 can arrange the center Wo of the substrate W at a position shifted in advance from the rotation center of the mounting table 211, and can reduce the amount of movement of the substrate W while ensuring the radius of rotation, thereby further reducing particles.

The recess 211c is formed in an elliptical shape in a plan view. Thus, the substrate processing apparatus 1 can easily move the substrate W in the long axis direction in the recess 211c of the mounting table 211B, and can facilitate the fixation of the substrate W in the mounting table 211B.

The second aspect of the present disclosure is the substrate processing method of a substrate processing apparatus that includes the processing container 11, the rotary table 21 rotatably provided inside the processing container 11, and the mounting tables 211, 211A, or 211B configured to mount a substrate W thereon, the mounting tables 211, 211A, or 211B being rotatable integrally with the rotary table 21 and being rotatable relative to the rotary table 21 at a position away from a rotation center of the rotary table 21. The method includes simultaneously rotating the rotary table 21 and the mounting tables 211, 211A, or 211B, and controlling, at a time of simultaneously rotating the rotary table 21 and the mounting tables 211, 211A, or 211B, rotation of the rotary table 21 and rotation of the mounting tables 211, 211A, or 211B in such a manner that an axial-rotation centrifugal force generated by the rotation of the mounting table 21 is larger than a revolution centrifugal force generated by the rotation of the rotary table 211, 211A, or 211B. Even in this case, the substrate processing method can suppress generation of particles.

The substrate processing apparatus 1 and the substrate transfer method according to the embodiment disclosed herein are illustrative and non-restrictive in all respects. The embodiments may be modified and improved in various forms without departing from the scope and spirit of the appended claims. The matters described in the plurality of embodiments can be combined with each other within a range not inconsistent with each other.

What is claimed is:

1. A substrate processing apparatus, comprising:
a processing container;
a rotary table rotatably provided inside the processing container;
a mounting table for mounting a substrate thereon, the mounting table being configured to be integrally rotatable with the rotary table and to be rotatable relative to the rotary table at a position away from a rotation center of the rotary table; and
a controller configured to control rotation of the rotary table and rotation of the mounting table, wherein
the controller controls rotation of the rotary table and rotation of the mounting table in such a manner that an axial-rotation centrifugal force generated by rotation of the mounting table is larger than a revolution centrifugal force generated by rotation of the rotary table.

2. The substrate processing apparatus according to claim 1, wherein
an axial rotation speed of rotation of the mounting table is higher than a revolution speed of rotation of the rotary table.

3. The substrate processing apparatus according to claim 2, wherein
the axial rotation speed is 2.5 times or more the revolution speed.

4. The substrate processing apparatus according to claim 3, wherein
the revolution speed is 40 rpm or higher, and the axial rotation speed is 10 times or more the revolution speed.

5. The substrate processing apparatus according to claim 1, wherein
a radius of rotation from a rotation center of the mounting table to a center of the substrate is equal to or less than 1/10 of a radius of rotation from a rotation center of the rotary table to the rotation center of the mounting table.

6. The substrate processing apparatus according to claim 1, wherein
the mounting table has a bottom surface on which the substrate is mounted, and a side wall which protrudes from an outer edge of the bottom surface and with which an outer edge of the substrate is contactable, and is provided with a recess surrounded by the bottom surface and the side wall.

7. The substrate processing apparatus according to claim 6, wherein
the recess is formed in a perfect circle shape in a plan view, and a center of the recess and the rotation center of the mounting table are shifted from each other.

8. The substrate processing apparatus according to claim 6, wherein
the recess is formed in an elliptical shape in a plan view.

9. A substrate processing method of a substrate processing apparatus, the apparatus including
a processing container;
a rotary table rotatably provided inside the processing container; and
a mounting table configured to mount a substrate thereon, the mounting table being rotatable integrally with the rotary table and being rotatable relative to the rotary table at a position away from a rotation center of the rotary table, the method comprising:
simultaneously rotating the rotary table and the mounting table; and
controlling, at a time of simultaneously rotating the rotary table and the mounting table, rotation of the rotary table and rotation of the mounting table in such a manner that an axial-rotation centrifugal force generated by the rotation of the mounting table is larger than a revolution centrifugal force generated by the rotation of the rotary table.
